(19) United States
(12) Patent Application Publication
(10) Pub. No.: US 2004/0235287 A1
(43) Pub. Date: Nov. 25, 2004

(54) Method of manufacturing semiconductor package and method of manufacturing semiconductor device

(75) Inventors: Akinobu Inoue, Nagano (JP); Atsunori Kajiki, Nagano (JP); Norio Yamanishi, Nagano (JP); Takashi Tsubota, Nagano (JP); Hiroyuki Takatsu, Nagano (JP)

Correspondence Address: ARMSTRONG, KRATZ, QUINTOS, HANSON & BROOKS, LLP, 1725 K STREET, NW, SUITE 1000, WASHINGTON, DC, 20006, US

(73) Assignee: SHINKO ELECTRIC INDUSTRIES CO., LTD., Nagano-shi (JP)

(21) Appl. No.: 10/834,975

(22) Filed: Apr. 30, 2004

(30) Foreign Application Priority Data
May 19, 2003 (JP) 2003-140558

(51) Int. Cl. H01L 21/44; H01L 21/50; H01L 23/495

(52) U.S. Cl. 438/612; 438/613; 438/108

(57) ABSTRACT

A method of manufacturing a semiconductor package includes the steps of: forming, on one side of polyimide film (insulating substrate), a first metal wiring layer (first conductive pattern) having a first pad; forming, on the other side of the polyimide film, a fourth metal wiring layer (second conductive pattern) having a second pad; forming, on the polyimide film, a first solder resist layer having an opening of a size sufficient to expose all side surfaces of the first pad; electrically connecting a semiconductor element to the first pad through a first solder bump; filling insulating adhesive into a space between the polyimide film and the semiconductor element; and bonding a second solder bump with the second pad by heating the second solder bump.

### BACKGROUND OF THE INVENTION

1. Field of the Invention

The present invention relates to a method of manufacturing a semiconductor package and to a method of manufacturing a semiconductor device. More specifically, the present invention relates to technologies useful for improving the yields of a semiconductor package and a semiconductor device.

2. Description of the Related Art

With the recent miniaturization of electronic gears, it has been demanded that semiconductor packages mounted on the electronic gears be miniaturized and that semiconductor packages be mounted at high density on mother boards in the electronic gears. Semiconductor packages satisfying such demand include a chip size package (CSP) whose outside dimensions are reduced to the dimensions of a semiconductor element by an innovation in the internal structure.

The above-described CSP includes various types. Out of the various types, a semiconductor package of a type called a ball grid array (BGA) can be mounted at high density on a mother board and greatly contributes to the miniaturization of electronic gears.

FIG. 1 is an enlarged cross-sectional view of a semiconductor package of the above-described BGA type. This package has an interposer 110 which is constructed by forming first and second conductive pads 103 and 107 on both sides of an insulating substrate 101, and a semiconductor element 105 is electrically connected to the first pads 103 through first solder bumps 104. Further, second solder bumps 108 which function as external connection terminals of this semiconductor package are bonded on the second pads 107 existing on the component side (i.e., side facing to mount board) of the interposer 110, and the above-described BGA is electrically connected on a mount board 111 through these second solder bumps 108.

The first bumps 104 are electrically connected to the first pads 103 by reflowing the first bumps 104. In order to prevent solder from adhering to a conductive pattern existing in the same plane as that of the first pads 103 during the reflow, a first solder resist layer 102 is formed on the insulating substrate 101 in a region except the first pads 103. For a similar reason, a second solder resist layer 106 is formed on the surface of the insulating substrate 101 where the second pads 107 are formed.

In the semiconductor package of this BGA type, in the case that the number of first solder bumps 104 is small, the bonding strength between the semiconductor element 105 and the interposer 110 is weakened, and a failure in conduction tends to occur between the semiconductor element 105 and the interposer 110. Accordingly, in general, insulating adhesive 109 called underfill resin is poured between the semiconductor element 105 and the interposer 110 to reinforce the bonding strength between the semiconductor element 105 and the interposer 110.

Note that, in the below-mentioned patent literatures 1, 2 and 3, technologies to electrically connect a semiconductor element to an interposer or a mount board through solder bumps as described above are disclosed, as technologies related to the present invention.

(Patent Literature 1)

Japanese Patent Laid-open Official Gazette No. Hei 11(1999)-87899

(Patent Literature 2)

Japanese Patent Laid-open Official Gazette No. Hei 11(1999)-150206

(Patent Literature 3)

Japanese Patent Laid-open Official Gazette No. Hei 11(1999)-297889

Incidentally, the second solder bumps 108 are bonded on the second pads 107 by reflowing the second solder bumps 108. By this reflow, the first solder bumps 104 are also heated and melted.

At this time, the volumes of the melted first solder bumps 104 are increased due to thermal expansion, whereas the adhesive 109 surrounding the first solder bumps 104 remains solid. Accordingly, the expanded solder bumps 104 exude into the interfaces between the solder resist 102 and the first pads 103 where the bonding strength is weak.

This results in a short circuit between adjacent first solder bumps 104 due to the solder having exuded as shown in the dotted-line circle. Therefore, the yield of the semiconductor package is lowered.

### SUMMARY OF THE INVENTION

An object of the present invention is to provide a method of manufacturing a semiconductor package and a method of manufacturing a semiconductor device in which methods yields can be improved.

According to an aspect of the present invention, there is provided a method of manufacturing a semiconductor package comprising: forming a first conductive pattern having a first pad on one side of an insulating substrate; forming a second conductive pattern having a second pad on the other side of the insulating substrate; forming a solder resist layer having an opening of a size sufficient to expose all side surface of the first pad on the one side of the insulating substrate; electrically connecting a semiconductor element on the first pad through a first solder bump; filling insulating adhesive into a space between the one side of the insulating substrate and the semiconductor element; and mounting a second solder bump on the second pad after filling the insulating adhesive, and bonding the second solder bump on the second pad by heating and melting the second solder bump.

According to the present invention, the opening of the solder resist layer is formed to have a size sufficient to expose all side surface of the first pad. Accordingly, the first pad and the solder resist layer do not overlap, and there is no interface therebetween. Accordingly, even in the case where the first solder bump is melted when the second solder bump is heated to be melted, the melted first solder bump does not exude to the interface between the first pad and the solder resist layer. Consequently, the risk of a short circuit between adjacent first solder bumps due to the solder having exuded can be reduced, and the yield of the semiconductor package can be improved.

Accordingly, the present invention is particularly useful for the case where the first solder bump is absolutely melted while the second solder bump is heated, as in the case where the heating temperature of the second solder bump is set equal to or higher than the melting point of the first solder bump.

Furthermore, a similar advantage to the above can be obtained not only in the case where the second solder bump is heated but also in the case where a thermal history of a temperature equal to or higher than the melting point of the first solder bump is given to the first solder bump.

Moreover, according to another aspect of the present invention, there is provided a method of manufacturing a semiconductor device comprising the step of electrically connecting the second solder bump on a terminal of a mount board by heating and melting the second solder bump included in the aforementioned semiconductor package.

According to the present invention, even in the case where the first solder bump of the semiconductor package is melted when the second solder bump is heated to be melted, adjacent first solder bumps can be prevented from being electrically short circuited for the aforementioned reason.

Such an advantage can also be obtained in the step of electrically connecting an electronic component on the mount board through solder melted by heating after connecting the second solder bump to the terminal.

### BRIEF DESCRIPTION OF THE DRAWINGS

FIG. 1 is a cross-sectional view of a semiconductor package according to a known example;

FIGS. 2A to 2E are cross-sectional views showing a method of manufacturing a semiconductor package according to an embodiment of the present invention in order of steps;

FIG. 3 is a cross-sectional view showing a method of manufacturing a semiconductor device according to the embodiment of the present invention; and

FIG. 4 is a graph showing the temperature profile of reflow in the embodiment of the present invention.

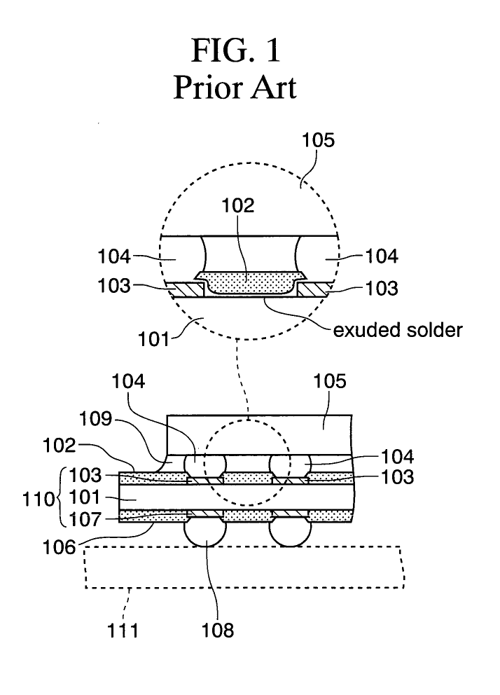

### DETAILED DESCRIPTION OF THE PREFERRED EMBODIMENT

Hereinafter, an embodiment of the present invention will be described based on drawings.

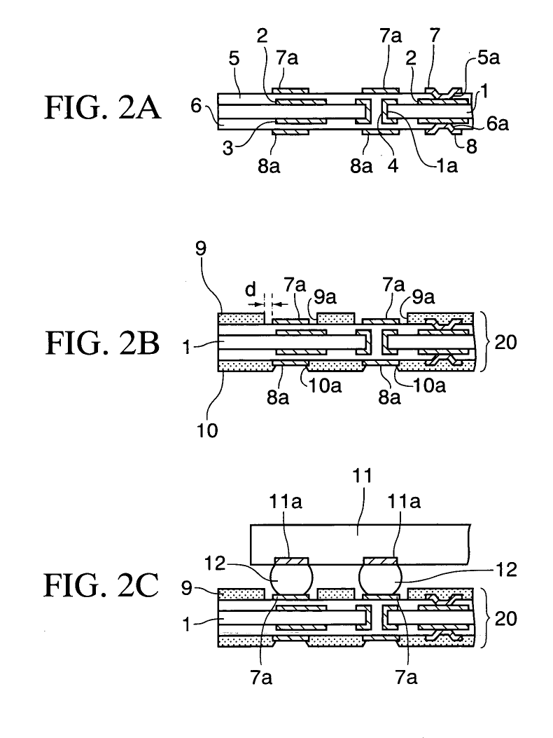

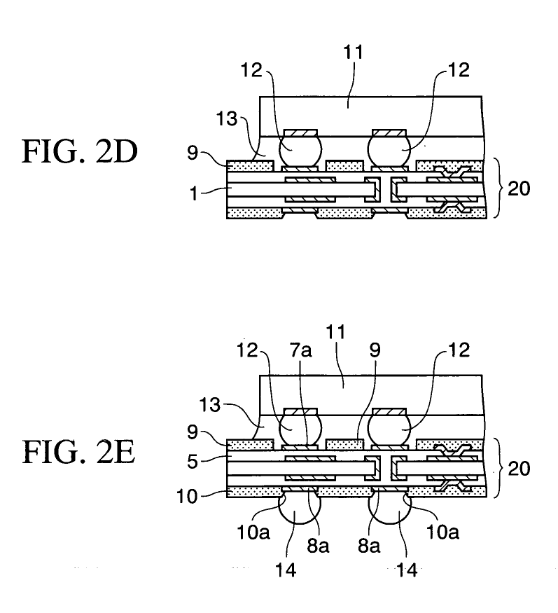

FIGS. 2A to 2E are cross-sectional views showing a method of manufacturing a semiconductor package according to the embodiment of the present invention in order of steps.

To begin with, explanation will be made for steps before the cross-sectional structure shown in FIG. 2A is obtained.

First, a through hole la is formed in a flexible polyimide film (insulating substrate) 1 with copper foil adhered to both sides thereof, by using a laser, a machine drill or the like. Subsequently, an electroless-plated copper layer is formed on the inner surface of this through hole la and the surfaces of the copper foil. Furthermore, an electroplated copper layer is grown on this electroless-plated copper layer, whereby a copper layer having a thickness of approximately 35 μm made of the copper foil and these plated copper layers is formed on the polyimide film 1. Thereafter, this copper layer is patterned, thereby forming the copper layers remaining on both sides of the polyimide film 1 into second and third level metal wiring layers 2 and 3. The metal wiring layers 2 and 3 are electrically connected through the copper-plated layer 4, made up with the electroplated and electroless-plated copper layers, located in the through hole 1a.

Subsequently, photosensitive polyimide resin is coated to a thickness of 30 μm to both sides of the polyimide film 1 by curtain coating, and then the photosensitive polyimide resin is exposed, developed, and heated to be cured. Thus, a first interlayer insulating layer 5 which has a first via hole 5a having a depth reaching to the second level metal wiring layer 2 is formed on the second level metal wiring layer 2, and a second interlayer insulating layer 6 which has a second via hole 6a having a depth reaching to the third level metal wiring layer 3 is formed on the third level metal wiring layer 3.

It should be noted that the insulating layers 5 and 6 may be made of non-photosensitive polyimide resin, epoxy resin or the like instead of photosensitive polyimide resin. In this case, the via holes 5a and 6a are formed by applying a beam of laser light to the respective insulating layers 5 and 6 to evaporate the resin in regions to which the beam of laser light has been applied.

Thereafter, an electroless-plated copper layer is formed on the surface of each insulating layer 5 and 6. Furthermore, using this electroless-plated copper layer as a feeding layer, an electroplated copper layer is grown. Thus, a copper layer having a thickness of approximately 13 μm constituted from these electroless-plated and electroplated copper layers is formed on each insulating layer 5 and 6. Then, the copper layer on the first interlayer insulating layer 5 is patterned into a first level metal wiring (first conductive pattern) 7, and the copper layer on the second interlayer insulating layer 6 is patterned into a fourth level metal wiring (second conductive pattern) 8.

The first metal wiring 7 is electrically connected to the second level metal wiring 2 through the first via hole 5a, and has first pads 7a to which solder bumps on a semiconductor element to be described later are to be bonded. The planar shape of each first pad 7a is circular, and the diameter thereof is approximately 100 μm.

Moreover, the fourth metal wiring 8 is electrically connected to the third level metal wiring 3 through the second via hole 6a, and has second pads 8a to which solder bumps functioning as external connection terminals of the package are to be bonded later. As in the case of the first pads 7a, the planar shape of each second pad 8a is circular, and the diameter thereof is approximately 400 μm.

Next, steps before the cross-sectional structure shown in FIG. 2B is obtained will be described.

First, solder resist made of photosensitive resin is coated on the first interlayer insulating layer 5, and the solder resist is exposed and developed to be formed into a first solder resist layer 9 having a thickness of approximately 23 μm. The first solder resist layer 9 has first openings 9a, each of which has a circular shape of a size sufficient to expose all side surfaces of a first pad 7a. The distance d between the inner surface of each first opening 9a and the side surface of each first pad 7a is approximately 50 μm. Further, the diameter of each first opening 9a is approximately 200 μm, but not particularly limited to it.

Thereafter, using a method similar to that used in the case that the first solder resist layer 9 has been formed, a second solder resist layer 10 is formed to a thickness of 33 μm on the second interlayer insulating layer 6. In the second solder resist layer 10, second openings 10a of a size sufficient to expose second pads 8a are formed.

Through the above-described steps, the basic structure of an interposer 20 with the solder resist layers 9 and 10 formed on both sides thereof is completed.

Next, steps before the cross-sectional structure shown in FIG. 2C is obtained will be described.

First, eutectic solder balls are mounted on electrode terminals 11a of a semiconductor element 11, and the eutectic solder balls are formed into first solder bumps 12 by reflowing the eutectic solder balls. Then, after the first solder bumps 12 have been cooled and solidified, the first solder bumps 12 are brought into contact with the first pads 7a. In this state, the first solder bumps 12 are reflowed at a temperature equal to or higher than the melting point thereof (approximately 183° C.).

Thus, the first solder bumps 12 are melted to wet the surfaces of the first pads 7a and spread thereon and, after the solder has been cooled and solidified, the semiconductor element 11 and the first pads 7a are electrically connected through the first solder bumps 12. Such a connection structure is also called flip-chip connection.

Further, a design of arranging the first solder bumps 12 is not particularly limited. In the present embodiment, fifty and some first solder bumps 12 are arranged in a grid on the electrode-forming surface of the semiconductor element 11.

Incidentally, in the case that there are a few, i.e., fifty and some, first solder bumps 12 as described above, the bonding strength between the semiconductor element 11 and the interposer 20 is weak overall, and the semiconductor element 11 tends to be peeled from the first pads 7a.

Accordingly, in the present embodiment, in order to compensate for this insufficient bonding strength, epoxy underfill resin is filled as insulating adhesive 13 into the space between the semiconductor element 11 and the first solder resist layer 9 as shown in FIG. 2D. The insulating adhesive 13 is liquid before and while filling but, after filling, this adhesive is heated to approximately 150° C. and solidified.

This insulating adhesive 13 makes the semiconductor element 11 hard to be peeled from the interposer 20 and can prevent a failure in the connection between the semiconductor element 11 and the first pads 7a.

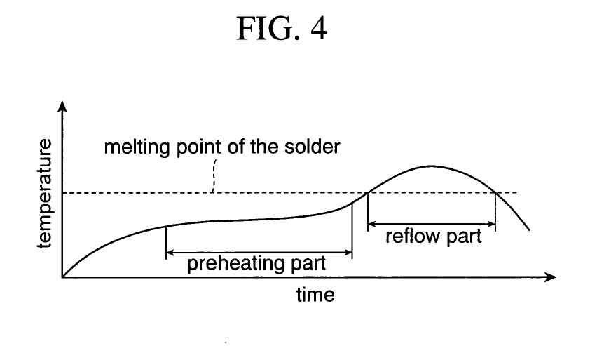

Subsequently, as shown in FIG. 2E, second solder bumps 14 made of eutectic solder of the same composition as that of the first solder bumps 12 are mounted on the second pads 8a, and the second solder bumps 14 are reflowed by hot air heating or far-infrared heating to be bonded with the second pads 8a. As shown in FIG. 4, the temperature profile of this reflow has a preheating part for heating the second solder bumps 14 at a temperature lower than the melting point (approximately 183° C.) of the eutectic solder, e.g., a temperature between 120° C. and 140° C., for 50 to 70 seconds, and a reflow part following the preheating part. Further, in the reflow part, the second solder bumps 14 are heated at a temperature equal to or higher than the melting point of the eutectic solder, e.g., temperature which is 225° C. at minimum and 245° C. at the peak thereof, for 40 to 60 seconds.

Note that the second solder bumps 14 before reflow may also be referred to as solder balls.

The second solder bumps 14 melted by such reflow are cooled and solidified to be bonded with the second pads 8a.

Through the above-described steps, the basic structure of the semiconductor package of the BGA type according to the present embodiment is completed.

According to the above-described embodiment, when the second solder bumps 14 are reflowed in the step shown in FIG. 2E, the first solder bumps 12 made of the same material as that of the second solder bumps 14 are also melted and thermally expands in the solidified insulating adhesive 13. However, since the first solder resist 9 is formed so that the first solder resist 9 does not overlap the first electrode pads 7a, there are no interfaces where the bonding strength between the first solder resist 9 and the first electrode pads 7a is weak, and the melted first solder bumps 12 do not exude along the interfaces.

Since this reduces the risk of a short circuit between adjacent solder bumps 12 due to solder which would exude in the interface, the yield of the semiconductor package can be improved.

It should be noted that the first interlayer insulating layer 5 has good adhesion with the first solder resist layer 9 compared with the first electrode pads 7a. Accordingly, melted solder hardly exudes from the interface between the first interlayer insulating layer 5 and the first solder resist layer 9.

Moreover, in the previous description, the exudation of the first solder bumps 12 during the reflow of the second solder bumps 14 has been considered. However, even in the case that a thermal history of a temperature at which the first solder bumps 12 are melted is given to this semiconductor package, an advantage similar to that described above can also be brought.

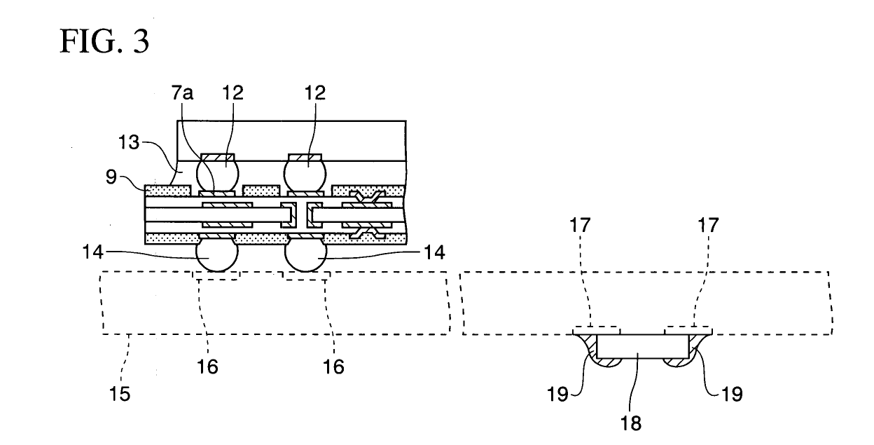

Such thermal histories include various reflow processes performed when the above-described semiconductor package is mounted on a mount board 15 to produce a semiconductor device as shown in the cross-sectional view of FIG. 3.

For example, in order to perform the above-described mounting, the entire structure is placed in a reflowing environment in the state where the second solder bumps 14 of the semiconductor package are in contact with first terminals 16 of the mount board 15. By this reflow, not only the second solder bumps 14 but also the first solder bumps 12 are melted. Even when the first solder bumps 12 are thus melted, adjacent first solder bumps 12 can be prevented from being electrically short circuited for the aforementioned reason.

Furthermore, in the case that electronic components 18, such as another semiconductor package and a chip capacitor, are electrically connected to second terminals 17 of the mount board 15 using solder 19 after the above-mentioned mounting has been finished, heat for melting the solder 19 is also applied to the semiconductor package. However, in this case, an advantage similar to that described above can also be brought.

These electronic components 18 may be mounted on only one side of the mount board 15 or may be mounted on both sides thereof. In particular, in the case that the electronic components 18 are mounted on both sides, two reflow processes are performed for the respective sides, and the first solder bumps 12 are melted every time each reflow process is performed. Accordingly, the effect of suppressing a short circuit between first solder bumps 12 significantly appears in this case.

Although the embodiment of the present invention has been described in detail, the present invention is not limited to the above-described embodiment.

For example, the polyimide film 1 having flexibility has been used in the steps previously described. However, instead of this, a rigid substrate, such as a glass epoxy substrate, may be used.

Further, in the previous description, a total of four wiring layers have been formed in the interposer 20. However, the number of wiring layers stacked is not limited to this, and five or more wiring layers may be formed. In this case, the above-described first pads 7a are formed in the uppermost wiring layer, and the above-described second pads 8a are formed in the lowermost wiring layer.

Furthermore, the aforementioned present invention can also be applied to the case that, instead of the semiconductor element 11, a CSP in which a rerouting layer connected to electrodes of a semiconductor element is formed on the semiconductor element and in which solder bumps are formed on pads in the rerouting layer, is mounted on the interposer 20.

As described above, according to the present invention, openings of a solder resist layer are formed to have a size sufficient to expose all side surfaces of a first pad. Accordingly, melted first solder bumps do not exude to the interfaces between the solder resist layer and the first pads, and the risk of a short circuit between adjacent first solder bumps can be reduced. In addition, the yield of a semiconductor package or a semiconductor device can be improved.

What is claimed is:

1. A method of manufacturing a semiconductor package comprising:
forming a first conductive pattern having a first pad on one side of an insulating substrate;
forming a second conductive pattern having a second pad on the other side of the insulating substrate;
forming a solder resist layer having an opening of a size sufficient to expose all side surface of the first pad on the one side of the insulating substrate;
electrically connecting a semiconductor element to the first pad through a first solder bump;
filling an insulating adhesive into a space between the one side of the insulating substrate and the semiconductor element; and
mounting a second solder bump on the second pad after filling the insulating adhesive, and bonding the second solder bump with the second pad by heating and melting the second solder bump.

2. The method according to claim 1, wherein heating temperature of the second solder bump is equal to, or higher than, a melting point of the first solder bump.

3. The method according to claim 1, wherein the first and second solder bumps are made of eutectic solder.

4. The method according to claim 1, wherein after the second solder bump has been bonded with the second pad, a thermal history of a temperature equal to, or higher than, a melting point of the first solder bump is given to the first solder bump.

5. The method according to claim 1, wherein one or more wiring layers are formed on the one side of the insulating substrate, and wherein the first conductive pattern is formed as an uppermost layer of the wiring layers.

6. The method according to claim 1, wherein one or more wiring layers are formed on the other side of the insulating substrate, and wherein the second conductive pattern is formed as a lowermost layer of the wiring layers.

7. A method of manufacturing a semiconductor device comprising:
forming a first conductive pattern having a first pad on one side of an insulating substrate;
forming a second conductive pattern having a second pad on the other side of the insulating substrate;
forming a solder resist layer having an opening of a size sufficient to expose all side surface of the first pad on the one side of the insulating substrate;
electrically connecting a semiconductor element on the first pad through the first solder bump;
filling insulating adhesive into a space between the one side of the insulating substrate and the semiconductor element;
mounting a second solder bump on the second pad after filling the insulating adhesive, and bonding the second solder bump on the second pad by heating and melting the second solder bump; and
electrically connecting the second solder bump to a terminal of a mount board by heating and melting the second solder bump after bonding the second solder bump with the second pad.

8. The method according to claim 7, wherein in the step of electrically connecting the second solder bump to the terminal of the mount board, heating temperature of the second solder bump is equal to, or higher than, a melting point of the first solder bump.

9. The method according to claim 7, further comprising: electrically connecting an electronic component to the mount board through solder melted by heating, after connecting the second solder bump to the terminal.
